(19) United States
(12) Patent Application Publication
(10) Pub. No.: US 2016/0351428 A1
(43) Pub. Date: Dec. 1, 2016

(54) WAFER TRANSPORT DEVICE

(71) Applicant: Episil Technologies Inc., Hsinchu City (TW)

(72) Inventors: Jain-Yuan Feng, Hsinchu City (TW); Tsai-Chi Chen, Hsinchu City (TW); Wen-Ying Cheng, Hsinchu City (TW); Chung-Yuan Cho, Hsinchu City (TW)

(21) Appl. No.: 14/829,658

(22) Filed: Aug. 19, 2015

(30) Foreign Application Priority Data
May 29, 2015 (TW) 104208533

(51) Int. Cl. H01L 21/677; H01L 21/687

(52) U.S. Cl. CPC H01L 21/67706; H01L 21/68735

(57) ABSTRACT

A wafer transport device including a robot arm, a first pin set and a mountable and dismountable C-ring. The robot arm has a first wafer carrying region. The first pin set is disposed on the robot arm and located in the first wafer carrying region. The mountable and dismountable C-ring is disposed on the first pin set and has a second wafer carrying region.

### CROSS REFERENCE TO RELATED APPLICATION

This application claims the priority benefit of Taiwan application serial no. 104208533, filed on May 29, 2015. The entirety of the above-mentioned patent application is hereby incorporated by reference herein and made a part of specification.

### BACKGROUND OF THE INVENTION

Field of the Invention

The invention is related to a wafer transport device, and particularly to a wafer transport device using a robot arm.

Description of Related Art

Original wafer transport robot arm can only transport wafers of a single size, and if wafers of the other sizes are to be transported, the wafer transport robot arm has to be modified and corrected for transporting the wafers of the other sizes.

However, the process of modifying and correcting the wafer transport robot arm is time-consuming, and a correcting error may cause a transport error to result in wafer waste, such that a manufacturing cost is increased. Moreover, frequent modification of the wafer transport robot arm may cause loss and deformation of components therein, such that a maintenance cost of the machine is increased.

### SUMMARY OF THE INVENTION

The invention provides a wafer transport device which may shorten the time for modifying and correcting a machine.

The invention provides a wafer transport device including a robot arm, a first pin set and a mountable and dismountable C-ring. The robot arm has a first wafer carrying region. The first pin set is disposed on the robot arm and located in the first wafer carrying region. The mountable and dismountable C-ring is disposed on the first pin set and has a second wafer carrying region.

In an embodiment of the invention, in the wafer transport device, the robot arm may have a first inclined surface in the first wafer carrying region.

In an embodiment of the invention, in the wafer transport device, the first inclined surface is, for example, a non-90-degree inclined surface, a 90-degree inclined surface or a combination thereof.

In an embodiment of the invention, in the wafer transport device, the first pin set includes at least one pin.

In an embodiment of the invention, in the wafer transport device, a length of the pin may be greater than a width of the mountable and dismountable C-ring so that the pin protrudes toward an inner portion of the mountable and dismountable C-ring.

In an embodiment of the invention, in the wafer transport device, the mountable and dismountable C-ring may have a second inclined surface in the second wafer carrying region.

In an embodiment of the invention, in the wafer transport device, the second inclined surface is, for example, a non-90-degree inclined surface, a 90-degree inclined surface or a combination thereof.

In an embodiment of the invention, the wafer transport device further includes a second pin set. The second pin set is disposed on the mountable and dismountable C-ring and located in the second wafer carrying region.

In an embodiment of the invention, in the wafer transport device, the second pin set includes at least one second pin.

In an embodiment of the invention, in the wafer transport device, the size of the wafer to be carried in the first wafer carrying region is, for example, greater than the size of the wafer to be carried in the second wafer carrying region.

In light of the above, in the wafer transport device provided by the invention, the mountable and dismountable C-ring is easy to be mounted and dismounted and can be utilized to switch the size of the wafer to be transported, thereby can effectively shorten the time for modifying and correcting the machine, thus can increase the utility rate of the machine. In addition, the mountable and dismountable C-ring may effectively reduce correcting error such that the high machine stability can be achieved; also, the waste of wafer caused by transport error may be avoided to reduce manufacturing cost of the products. In addition, since the mountable and dismountable C-ring results in less loss and deformation of the component during a mounting and dismounting process, the maintenance cost of the machine may be decreased.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an explosive view illustrating a wafer transport device according to an embodiment of the invention.

FIG. 2 is an assembly view illustrating a wafer transport device according to an embodiment of the invention.

FIG. 3 is a top view illustrating a mountable and dismountable C-ring shown by FIG. 1.

FIGS. 4A-4C are cross-sectional views illustrating a robot arm shown by FIG. 1 along a section line I-I′.

FIGS. 5A-5C are cross-sectional views illustrating the mountable and dismountable C-ring shown by FIG. 1 along a section line II-II′.

### DESCRIPTION OF EMBODIMENTS

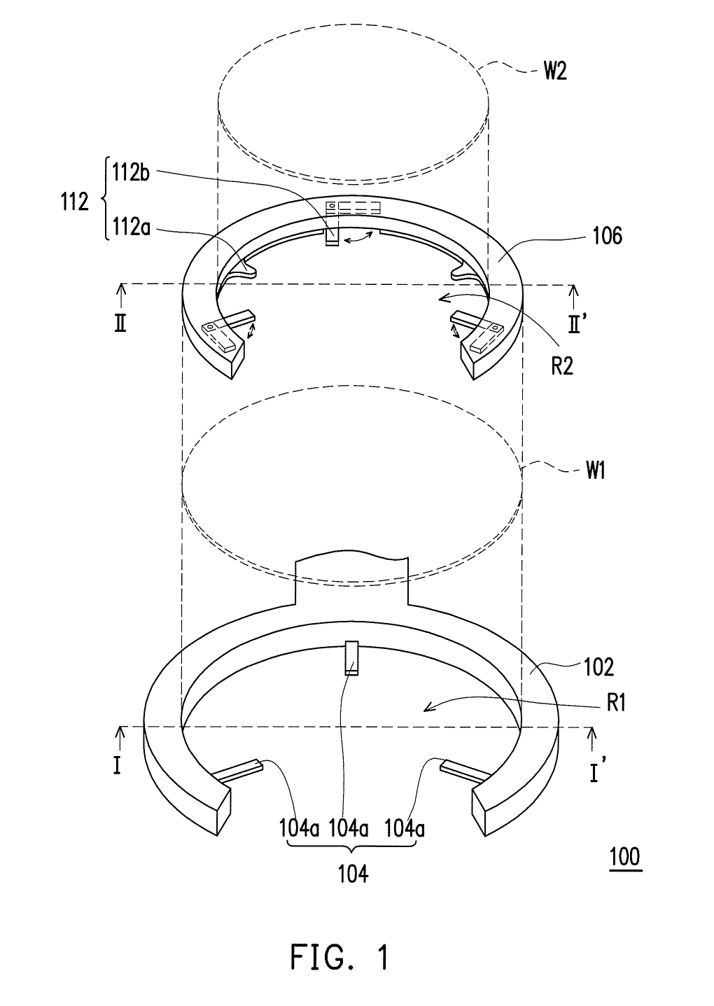

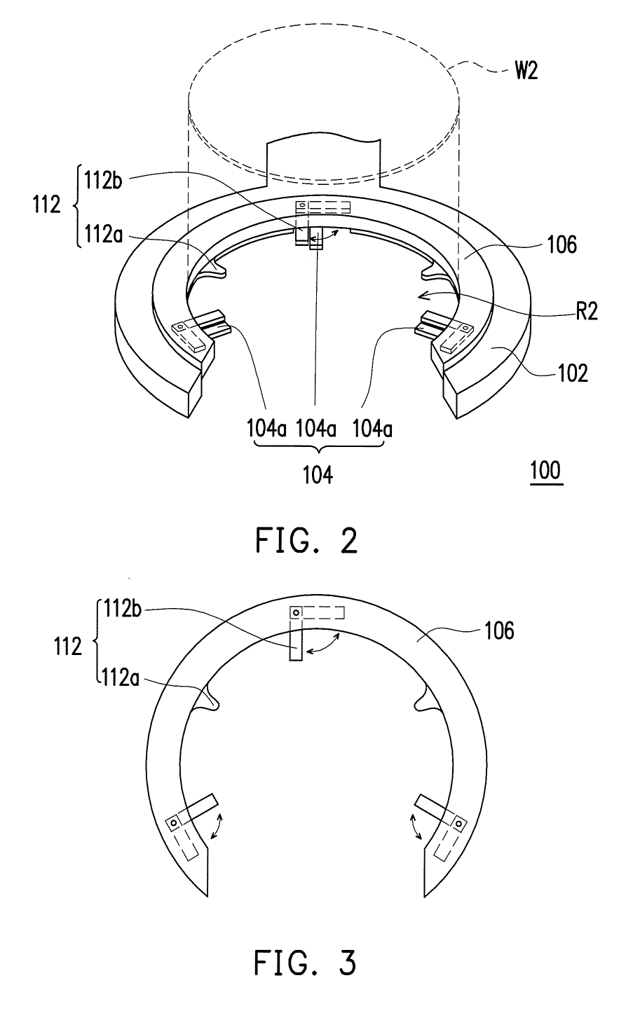

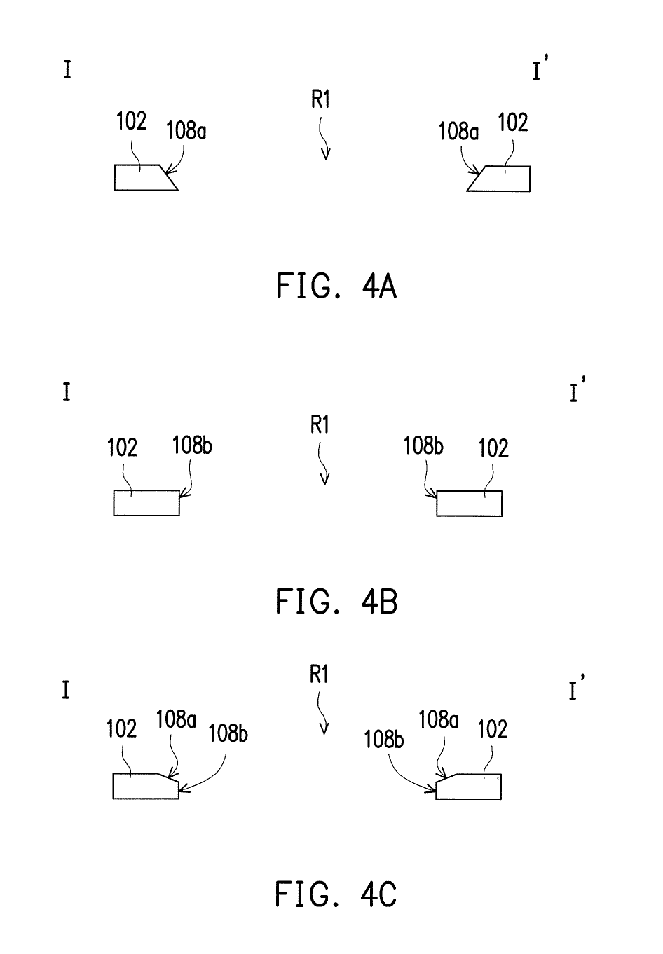

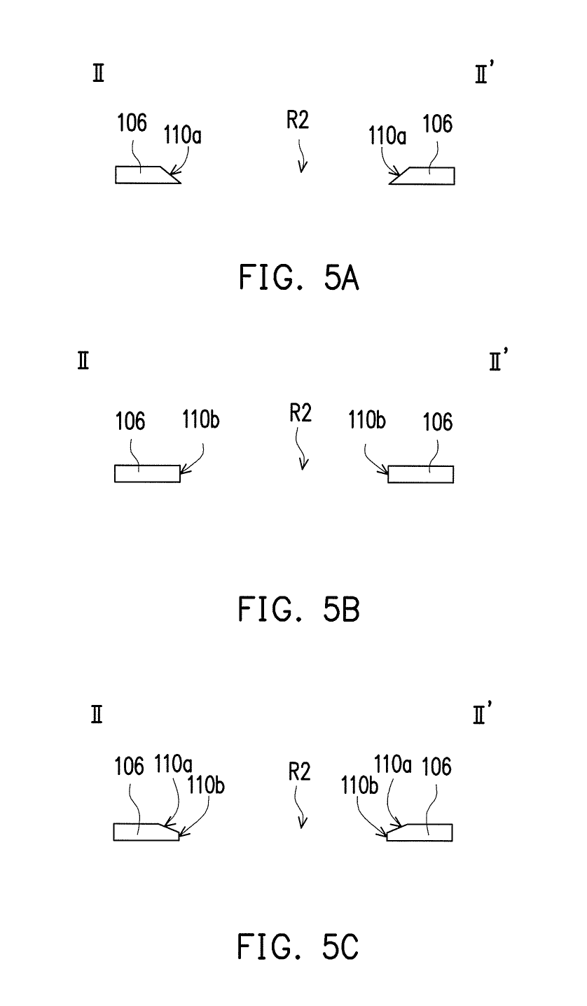

FIG. 1 is an explosive view illustrating a wafer transport device according to an embodiment of the invention. FIG. 2 is an assembly view illustrating a wafer transport device according to an embodiment of the invention. FIG. 3 is a top view illustrating a mountable and dismountable C-ring shown by FIG. 1. FIGS. 4A-4C are sectional views illustrating a robot arm shown by FIG. 1 along a sectional line I-I′. FIGS. 5A-5C are sectional views illustrating the mountable and dismountable C-ring shown by FIG. 1 along a sectional line II-II′.

Referring to FIGS. 1-3, a wafer transport device 100 includes a robot arm 102, a pin set 104 and a mountable and dismountable C-ring 106. The wafer transport device 100 is adapted to transport wafers of different sizes in various semiconductor processes (for example, a photolithography process). For example, under the condition that the wafer transport device 100 is not equipped with the mountable and dismountable C-ring 106, the wafer transport device 100 may be used to transport a wafer W1. Under the condition that the wafer transport device 100 is equipped with the mountable and dismountable C-ring 106, the wafer transport device 100 may be used to transport a wafer W2.

The robot arm 102 has a wafer carrying region R1. The wafer carrying region R1 may be used to accommodate the wafer W1. A material of the robot arm 102 is, for example, Teflon, metal alloy, ceramic, or PVC, etc., that is not liable to be deformed.

Referring to FIGS. 4A-4C, the robot arm 102 in the wafer carrying region R1 may have a inclined surface 108a and/or an inclined surface 108b, for example, the non-90-degree inclined surface 108a in FIG. 4A, the 90-degree inclined surface 108b in FIG. 4B, or a combination of the non-90-degree inclined surface 108a and the 90-degree inclined surface 108b in FIG. 4C. Under the condition that the robot arm 102 has the non-90-degree inclined surface 108a, it avails placing the wafer W1 in the wafer carrying region R1. Moreover, based on a section difference of the robot arm 102, the wafer W1 can be stably kept in the wafer carrying region R1 even when the robot arm 102 moves.

Further referring to FIGS. 1-3, the pin set 104 is disposed on the robot arm 102 and located in the wafer carrying region R1 for carrying the wafer W1. The pin set 104 includes at least one pin 104a. A material of the pin 104a is, for example, Teflon, metal alloy, ceramic, or PVC, etc., that is not liable to be deformed. The pin 104a and the robot arm 102 may be independent members or may be formed integrally. In the embodiment, an implementation that the pin set 104 has three pins 104a separated from each other is taken as an example for description, though the invention is not limited thereto. In the meantime, the spirit of the invention is met as long as the pattern and the number of the designed pin 104a can be adapted to stably carry the wafer W1, and those skilled in the art can adjust the pattern and the number of the pin 104a according to an actual design requirement. For example, in another embodiment, the pin set 104 may have a single C-ring pin only.

The mountable and dismountable C-ring 106 is disposed on the pin set 104 and has a wafer carrying region R2. A material of the mountable and dismountable C-ring 106 is, for example, Teflon, metal alloy, ceramic, or PVC, etc., that is not liable to be deformed. The wafer carrying region R2 may be used to accommodate the wafer W2. The size of the wafer W1 to be carried in the wafer carrying region R1 is, for example, greater than the size of the wafer W2 to be carried in the wafer carrying region R2, such that the wafer transport device 100 may transport wafers W1 and W2 with different sizes. Specifically, under the condition that the mountable and dismountable C-ring 106 is not disposed on the pin set 104, the wafer transport device 100 may be used to transport the wafer W1. Under the condition that the mountable and dismountable C-ring 106 is disposed on the pin set 104, the wafer transport device 100 may be used to transport the wafer W2.

Referring to FIGS. 5A-5C, the mountable and dismountable C-ring 106 in the wafer carrying region R2 may have an inclined surface 110a and/or 110b, for example, the non-90-degree inclined surface 110a in FIG. 5A, the 90-degree inclined surface 110b in FIG. 5B, or a combination of the non-90-degree inclined surface 110a and the 90-degree inclined surface 110b in FIG. 5C. Under the condition that the mountable and dismountable C-ring 106 has the non-90-degree inclined surface 110a, it avails placing the wafer W2 in the wafer carrying region R2. Moreover, based on a section difference of the mountable and dismountable C-ring 106, the wafer W2 can be stably kept in the wafer carrying region R2 even when the robot arm 102 moves.

Further referring to FIGS. 1-3, a length of the pin 104a may be greater than a width of the mountable and dismountable C-ring 106 so that the pin protrudes toward an inner portion of the mountable and dismountable C-ring 106. Accordingly, the pin 104a may be used to carry the wafer W2 in the wafer carrying region R2.

In addition, the wafer transport device 100 may further selectively include a pin set 112. The pin set 112 is disposed on the mountable and dismountable C-ring 106 and located in the wafer carrying region R2. The pin set 112 includes at least one pin 112a. The pin 112a is, for example, a fixed type pin for carrying the wafer W2. The pin 112a and the mountable and dismountable C-ring 106 may be formed integrally or may be independent members. A material of the pin 112a is, for example, Teflon, metal alloy, ceramic, or PVC, etc., that is not liable to be deformed. The pin set 112 may further include at least one pin 112b. The pin 112b is, for example, used for being fixed with the original transport device. A material of the pin 112b is, for example, Teflon, metal alloy, ceramic, or PVC, etc., that is not liable to be deformed. In the embodiment, an implementation that the pin set 112 has two fixed-type pins 112a separated from each other and three movable pins 112b is taken as an example for description, though the invention is not limited thereto. In the meantime, the spirit of the invention is met as long as the pattern and the number of the designed pin 112a can be adapted to stably carry the wafer W2, and those skilled in the art can adjust the pattern and the number of the pin 112a according to an actual design requirement. For example, in another embodiment, the pin 112a may be a single C-ring pin. In addition, the spirit of the invention is met as long as the pattern and the number of the designed pin 112b can be adapted to be fixed with the original transport device, and those skilled in the art can adjust the pattern and the number of the pin 112b according to an actual design requirement.

In addition, under the condition that the wafer transport device 100 has the pin set 112, the pin set 112 may be used to carry the wafer W2. In that case, the length of the pin 104a may be less than or equivalent with the width of the mountable and dismountable C-ring 106 so that the pin does not protrude toward the inner portion of the mountable and dismountable C-ring 106.

The above embodiments show that, in the wafer transport device 100 described by the above embodiments, the mountable and dismountable C-ring 106 is easy to be mounted and dismounted and may be used to switch the size of the wafer to be transported, thereby may effectively shorten the time for modifying and correcting machine, thus can improve utility rate of the machine. In addition, the correcting error may be effectively decreased by using the mountable and dismountable C-ring 106, such that high machine stability can be achieved. Also, the waste of wafer results from transport error can be avoided, thereby reducing the manufacturing cost of the product. Meanwhile, since the mountable and dismountable C-ring 106 results in less loss and deformation of the component during the mounting and dismounting process, the maintenance cost of the machine can be reduced.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A wafer transport device, comprising:
a robot arm, having a first wafer carrying region;
a first pin set, disposed on the robot arm and located in the first wafer carrying region; and
a mountable and dismountable C-ring, disposed on the first pin set and having a second wafer carrying region.

2. The wafer transport device as claimed in claim 1, wherein the robot arm has a first inclined surface in the first wafer carrying region.

3. The wafer transport device as claimed in claim 2, wherein the first inclined surface comprises a non-90-degree inclined surface, a 90-degree inclined surface or a combination thereof.

4. The wafer transport device as claimed in claim 1, wherein the first pin set comprises at least one pin.

5. The wafer transport device as claimed in claim 4, wherein a length of the at least one pin is greater than a width of the mountable and dismountable C-ring so that the pin protrudes toward an inner portion of the mountable and dismountable C-ring.

6. The wafer transport device as claimed in claim 1, wherein the mountable and dismountable C-ring has a second inclined surface in the second wafer carrying region.

7. The wafer transport device as claimed in claim 6, wherein the second inclined surface comprises a non-90-degree inclined surface, a 90-degree inclined surface or a combination thereof.

8. The wafer transport device as claimed in claim 1, further comprising a second pin set disposed on the mountable and dismountable C-ring and located in the second wafer carrying region.

9. The wafer transport device as claimed in claim 8, wherein the second pin set comprises at least one second pin.

10. The wafer transport device as claimed in claim 1, wherein a size of a wafer to be carried in the first wafer carrying region are greater than a size of a wafer to be carried in the second wafer carrying region.
